(19) United States
(12) Patent Application Publication
(10) Pub. No.: US 2020/0218165 A1
(43) Pub. Date: Jul. 9, 2020

(54) EXPOSURE APPARATUS AND METHOD OF DETECTING ALIGNMENT ERROR OF RETICLE

(71) Applicant: XIA TAI XIN SEMICONDUCTOR (QING DAO) LTD., Qingdao (CN)

(72) Inventor: JIYONG YOO, Singapore (SG)

(21) Appl. No.: 16/660,733

(22) Filed: Oct. 22, 2019

Related U.S. Application Data
(60) Provisional application No. 62/784,288, filed on Dec. 21, 2018.

(51) Int. Cl. G03F 7/20

(52) U.S. Cl. CPC G03F 7/70633; G03F 7/70608; G03F 7/70741

(57) ABSTRACT

The present disclosure provides an exposure apparatus for transferring a pattern of a reticle onto a wafer. The reticle has a metallic layer forming the pattern at one side of the reticle. The pattern includes at least one circuit pattern and at least one alignment mark. The exposure apparatus includes an exposure light source, an alignment light source, a reticle stage, and an alignment sensor. The exposure light source is configured to provide a first light to expose the pattern of the reticle. The alignment light source is configured to provide a second light to expose the alignment mark of the reticle. The reticle stage is configured to position the reticle. The alignment sensor is configured to detect the second light penetrated through the alignment mark of the reticle for determining an alignment error of the reticle.

### CROSS-REFERENCE TO RELATED APPLICATION(S)

This application claims the benefit of U.S. Provisional Patent Application No. 62/784288, filed on Dec. 21, 2018, the contents of which are incorporated by reference herein.

### FIELD

The present disclosure generally relates to an exposure apparatus and a method of detecting an alignment error of a reticle. More specifically, the present disclosure relates to an exposure apparatus having an alignment light source and an alignment sensor to allow the detection of an alignment error of a reticle during an exposure process.

### BACKGROUND

Integrated circuits are generally made by photolithographic processes (or exposure processes) that use reticles (or photomasks) and an associated light source to project a circuit image on the surface of a semiconductor wafer. The photolithography process entails coating the wafer with a layer of photoresist, exposing the layer of photoresist, and then developing the exposed photoresist. During the process of exposing the layer of photoresist (e.g., an exposure process), the wafer coated with a layer of photoresist is loaded to at an exposure apparatus (e.g., a scanner or stepper) to be exposed with a pattern of a reticle.

As shown in FIG. 1A, a schematic diagram of an exposure apparatus is illustrated. During the exposure process, a reticle 110 is positioned on a reticle stage 130 of an exposure apparatus. The reticle 110 is made from a flat piece of quartz layer 111 (or soda-lime glass layer) coated with a metallic layer 112 (e.g., a chromium layer) forming a pattern for an electronic circuit. A pellicle 120 is used to seal the reticle, so as to isolate and protect the pattern of the reticle surface from particulate contamination and eliminate dust or other particles from the focal plane of the pattern. The exposure apparatus generates an ultraviolet light (such as deep ultraviolet (DUV) light) to expose the reticle 110. When the reticle 110 is exposed continuously, the reticle 110 may absorb radiation energy from the ultraviolet light, resulting in temperature increase of the reticle 110. The reticle 110 may deform due to thermal expansion and lead to an increase in alignment error of the reticle 110. As shown in FIG. 1B, the dashed lines indicate an original shape of the reticle 110; and the solid lines indicate an expanded shape of the reticle 110. The alignment error of the reticle 110 may cause the pattern transmitted onto the wafer to change, distort, or alter from its intended design, ultimately impacting the quality of the semiconductor device manufactured. Realignment between the reticle and the wafer must be repeatedly performed during the exposure process. However, the detection of alignment error and realignment process is often time consuming and results in a prolonged exposure time of the wafer.

In light of the increasing complexity of semiconductor manufacturing process and the shrinking of semiconductor geometry, there is a need to improve alignment error detection and realignment of an exposure process.

### SUMMARY

In view of above, an object of the present disclosure is to provide an exposure apparatus and a method of detecting alignment error of reticle during an exposure process for a semiconductor wafer. The method and the exposure apparatus can reduce the processing time of the exposure process.

To achieve the above object, an implementation of the present disclosure provides an exposure apparatus for transferring a pattern of a reticle onto a wafer. The reticle has a metallic layer forming the pattern at one side of the reticle. The pattern includes at least one circuit pattern and at least one alignment mark. The exposure apparatus includes an exposure light source, an alignment light source, a reticle stage, and an alignment sensor. The exposure light source is configured to generate a first light to expose the pattern of the reticle. The alignment light source is configured to generate a second light to expose the alignment mark of the reticle. The reticle stage is configured to position the reticle. The alignment sensor is configured to detect the second light penetrated through the alignment mark of the reticle for determining an alignment error of the reticle.

To achieve the above object, another implementation of the present disclosure provides a method of detecting an alignment error of a reticle during an exposure process. The exposure process transfers a pattern of the reticle onto a wafer. The reticle has a metallic layer forming the pattern at one side of the reticle. The pattern includes at least one circuit pattern and at least one alignment mark. The method includes several actions. In an action, an exposure apparatus is provided. The exposure apparatus includes an exposure light source, an alignment light source, a reticle stage, and an alignment sensor. In an action, the reticle is disposed on the reticle stage of the exposure apparatus. In an action, the exposure light source of the exposure apparatus provides a first light to expose the pattern of the reticle. In step S404, the alignment light source of the exposure apparatus provides a second light to expose the alignment mark of the reticle. In an action, the pattern of the reticle is projected onto the wafer by the first light penetrated through the pattern of the reticle. In an action, the alignment sensor detects the second light penetrated through the alignment mark of the reticle. In an action, the alignment error is determined based on the second light detected by the alignment sensor. A realignment process between the reticle and the wafer is performed according to the alignment error determined by a control unit. In one implementation, the position of the reticle stage is adjusted according to the alignment error. In another implementation, the position of the wafer stage is adjusted according to the alignment error. In some implementations, the positions of the reticle stage and the wafer stage are adjusted according to the alignment error.

As described above, the exposure apparatus of the implementations of the present disclosure uses an additional light source for detecting the alignment error of the reticle. While the exposure light source generates an exposure light to expose the pattern of the reticle, the alignment light source generates a detecting light to expose the alignment mark of the reticle. The detecting light penetrates through the alignment mark of the reticle and is detected by an alignment sensor for alignment error detection. The exposure apparatus of the present disclosure can perform alignment error detection of the reticle without halting the exposure process. Therefore, the exposure apparatus of the implementations of the present disclosure can reduce the processing time of the exposure process, and hence improving the processing rate of the wafer.

### BRIEF DESCRIPTION OF THE DRAWINGS

Implementations of the present technology will now be described, by way of example only, with reference to the attached figures.

FIG. 1A is a schematic diagram showing an exposure apparatus; and FIG. 1B is a schematic diagram showing a deformation of a reticle of FIG. 1A.

FIG. 2A is a schematic diagram of an exposure apparatus according to a first implementation of the present disclosure; FIG. 2B is a schematic diagram of a reticle of the first embodiment; and FIGS. 2C and 2D are schematic diagrams showing a reticle alignment error detecting process of the exposure apparatus of FIG. 2A.

FIGS. 3A and 3B are schematic diagrams of an exposure apparatus according to a second implementation of the present disclosure; FIG. 3C is a schematic diagram showing an exposure process of the exposure apparatus of FIG. 3A; and FIG. 3D is a schematic diagram showing an alignment error detecting process during the exposure process of the exposure apparatus of FIG. 3A.

FIG. 4 is a flowchart of a method of detecting an alignment error of a reticle during an exposure process according to a third implementation of the present disclosure.

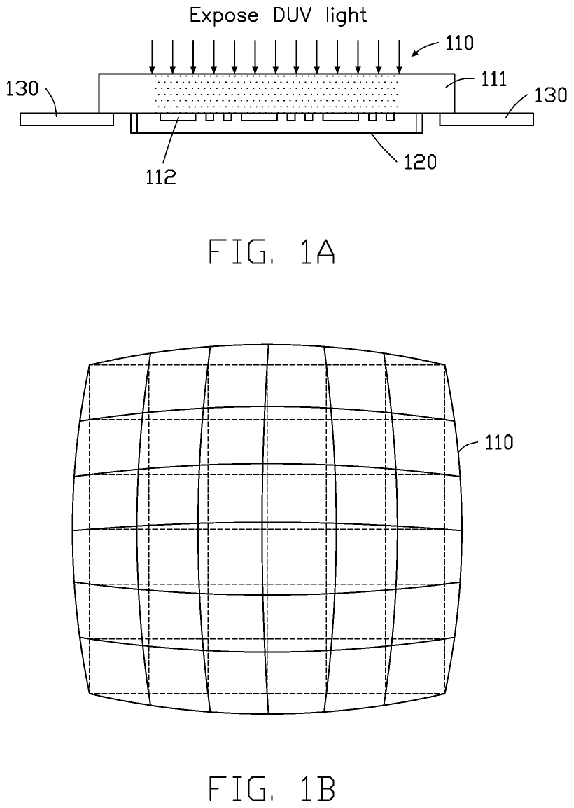

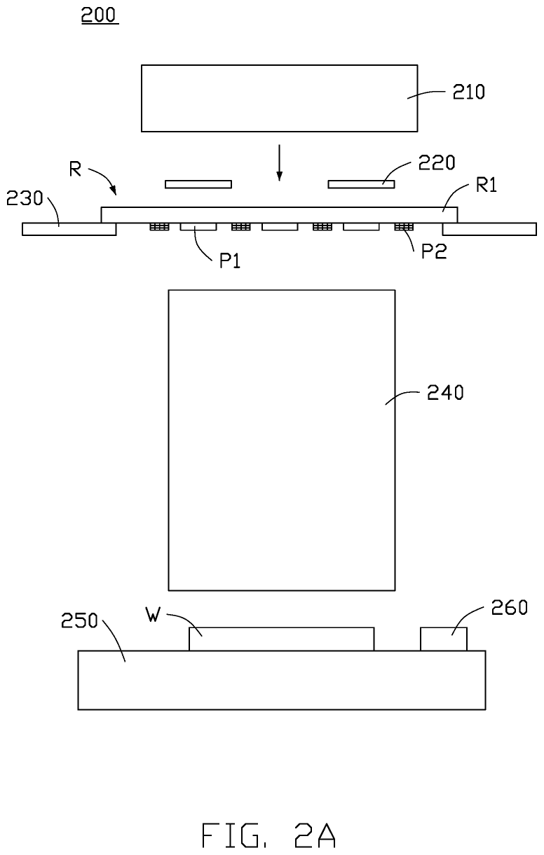

### DETAILED DESCRIPTION

The present disclosure will now be described more fully hereinafter with reference to the accompanying drawings, in which exemplary implementations of the disclosure are shown. This disclosure may, however, be embodied in many different forms and should not be construed as limited to the exemplary implementations set forth herein. Rather, these exemplary implementations are provided so that this disclosure will be thorough and complete, and will fully convey the scope of the disclosure to those skilled in the art. Like reference numerals refer to like elements throughout.

The terminology used herein is for the purpose of describing particular exemplary implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

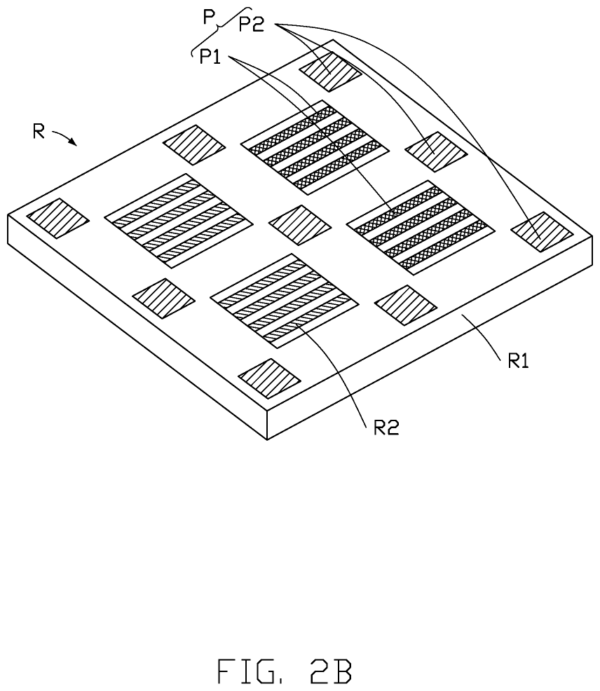

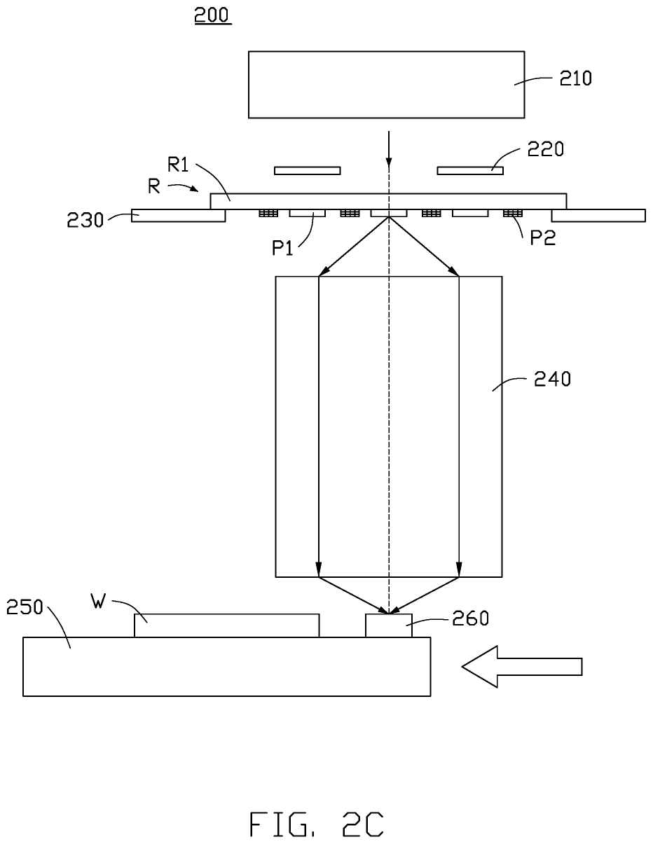

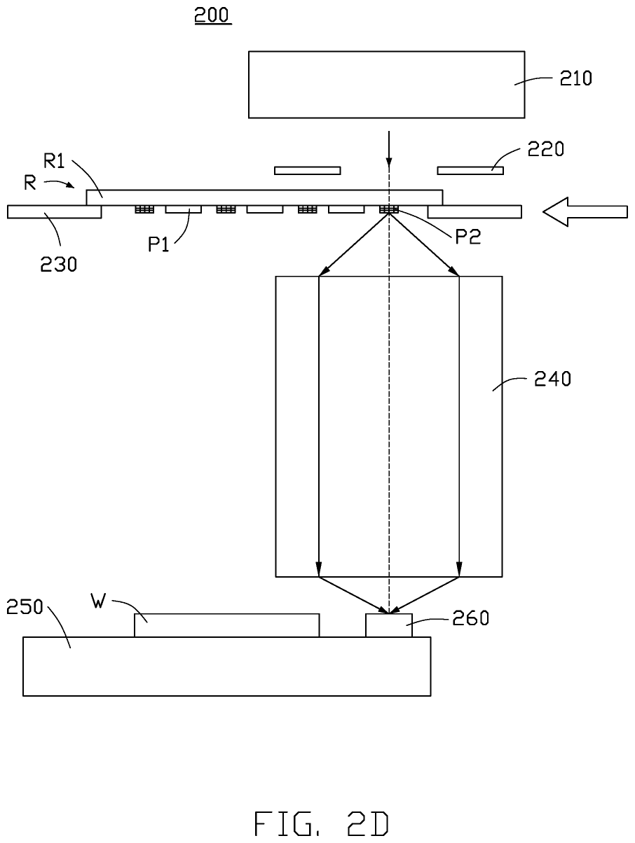

The description will be made as to the exemplary implementations of the present disclosure in conjunction with the accompanying drawings in FIGS. 2A to 4. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 2A, a schematic diagram of an exposure apparatus 200 according to a first implementation of the present disclosure is illustrated. As shown in FIG. 2A, the exposure apparatus 200 includes an illumination module 210, an exposure slit 220, a reticle stage 230, a projection module 240, a wafer stage 250, and an image sensor 260. The exposure apparatus 200 is configured to transfer a pattern of a reticle R onto a wafer W.

Referring to FIG. 2B, the reticle R includes a transparent layer R1 and a metallic layer R2. The metallic layer R2 is disposed on the transparent layer R1 and forms the pattern P at one side of the reticle R. The pattern P includes at least one circuit pattern P1 and at least one alignment mark P2. The alignment mark P2 may be an Advanced Imaging Metrology (AIM) mark consisting of several groups of parallel lines. In some implementations, the alignment mark P2 may be a Box In Box mark consisting of a plurality of box patterns. The circuit pattern P1 is configured to form a circuit image on the wafer W. The alignment mark P2 is configured to align the reticle R to the wafer W. The transparent layer R1 of the reticle R may be a quartz layer or a soda-lime glass layer. The metallic layer R2 of the reticle R has gaps and lines for forming the pattern for transferring the circuit image to the wafer W. Preferably, the metallic layer R2 is a chromium layer.

The illumination module 210 of the exposure apparatus 200 is configured to illuminate the reticle R by light provided from a light source (not shown in the figure). The light can be deep ultraviolet (DUV) light. The exposure slit 220 is disposed between the illumination module 210 and the reticle stage 230. The light passes through the exposure slit 220 before passing through the reticle R. The exposure slit 220 is generally at least as wide as an exposure field of the reticle R, but only a fraction of a length of the reticle R. The reticle stage 230 is configured to position the reticle R. The projection module 240 is configured to project the pattern of the reticle R onto the wafer W by the light penetrated through the pattern of reticle R. The wafer stage 250 is configured to position the wafer W. The image sensor 260 is configured to detect the light penetrated through the alignment mark P2 of the reticle R for determining an alignment error of the reticle R. The image sensor 260 may be disposed on the wafer stage W. A control unit (not shown in the figure) is coupled to the image sensor 260 to determine an alignment error of the reticle R based on the light detected by the image sensor 260 and further adjust positions of the reticle stage 230 and the wafer stage 250 for realignment.

During an exposure process, detection of alignment error of the reticle R and realignment must be repeatedly performed due to thermal expansion of the reticle R caused by absorption of radiation energy. When detecting the alignment error of the reticle R, as shown in FIG. 2C, the wafer stage 250 is moved to a position where the image sensor 260 is exposed to the light from the illumination module 210. Then, the reticle stage 230 is moved to a position where alignment mark P2 of the reticle R is exposed to the light from the illumination module 210, as shown in FIG. 2D. In such way, the light from the illumination module 210 passes through the exposure slit 220, penetrates through the alignment mark P2, passes through the projection module 240, and then is detected by the image sensor 260. Based on the light detected by the image sensor 260, the alignment error of the reticle R is then determined by the control unit coupled to the image sensor 260. The control unit may further adjust the positions of the reticle stage 230 and/or the wafer stage 250 to perform realignment between the reticle R and the wafer W. However, when detecting the alignment error of the reticle R, the exposure process of the wafer W halts operation until the positions of the reticle stage 230 and the wafer stage 250 are adjusted for realignment between the reticle R and the wafer W. Such alignment error detection and realignment processes are repeatedly performed during the exposure process. Therefore, the processing time of the exposure process for the wafer W is prolonged, resulting in a low processing rate of the wafer W.

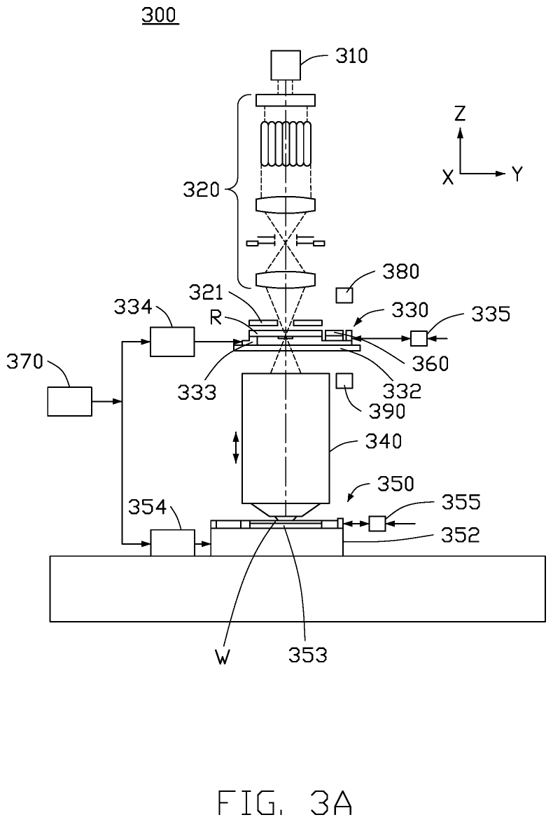

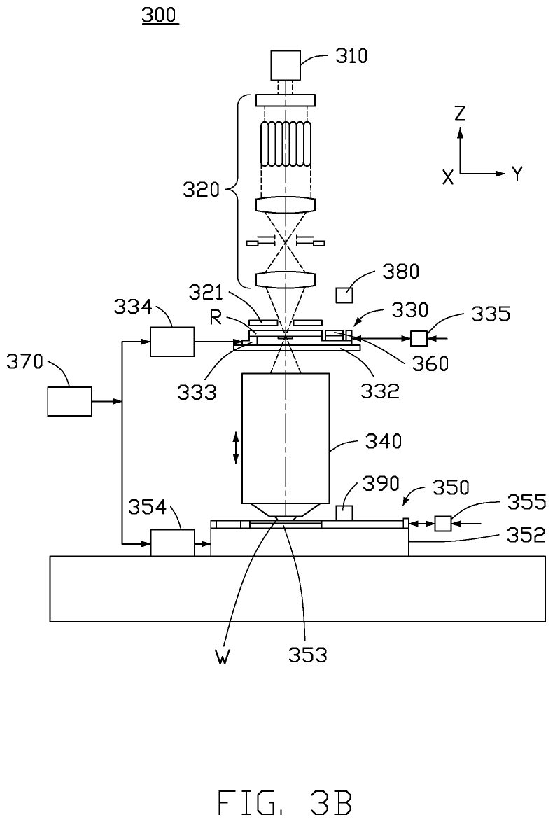

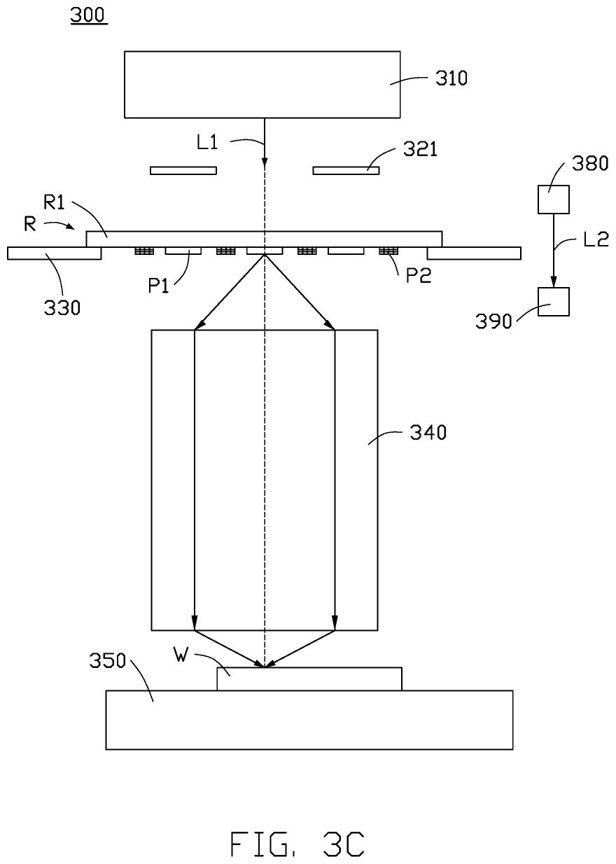

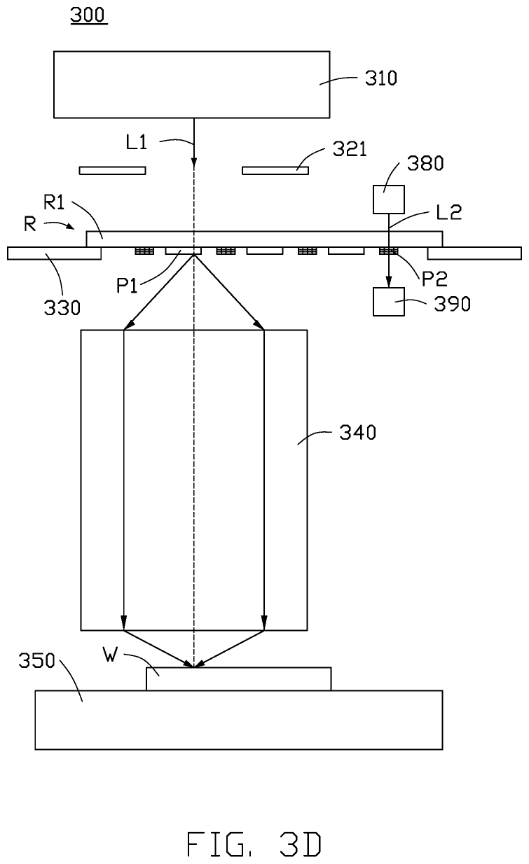

Referring to FIGS. 3A and 3B, schematic diagrams of an exposure apparatus 300 according to a second implementation of the present disclosure are illustrated. As shown in FIG. 3A, the exposure apparatus 300 is a lithography apparatus for transferring a pattern of a reticle onto a wafer W. The reticle can be referred to the reticle R in FIG. 2B. The reticle R includes a transparent layer R1 and a metallic layer R2. The metallic layer R2 is disposed on the transparent layer R1 and forms the pattern P at one side of the reticle R. The pattern P includes at least one circuit pattern P1 and at least one alignment mark P2. The alignment mark P2 may be an Advanced Imaging Metrology (AIM) mark consisting of several groups of parallel lines. In some implementations, the alignment mark P2 may be a Box In Box mark consisting of a plurality of box patterns. The circuit pattern P1 is configured to form a circuit image on the wafer W. The alignment mark P2 is configured to align the reticle R to the wafer W. The transparent layer R1 of the reticle R may be a quartz layer or a soda-lime glass layer. The metallic layer R2 of the reticle R has gaps and lines for forming the pattern for transferring the circuit image to the wafer W. Preferably, the metallic layer R2 is a chromium layer. The exposure apparatus 300 includes an exposure light source 310, an alignment light source 380, a reticle stage 330, and an alignment sensor 390. The exposure light source 310 is configured to generate a first light to expose the pattern of the reticle R. The first light may be deep ultraviolet (DUV) light. The pattern P of the reticle R is exposed to the first light provided from the exposure light source 310 and then transferred onto the wafer W. The alignment light source 380 is configured to generate a second light to expose the alignment mark P2 of the reticle R. The second light may be helium-neon laser light having a wavelength of about 632.8 nm. The alignment mark P2 of the reticle R is exposed to the second light provided from the alignment light source 380. The reticle stage 330 is configured to position the reticle R. The alignment sensor 390 is configured to detect the second light provided from the alignment light source 380 and penetrated through the alignment mark P2 of the reticle R for determining an alignment error of the reticle R.

The exposure apparatus 300 further includes an illumination module 320, an exposure slit 321, a projection module 340, and a wafer stage 350. The illumination module 320 is configured to illuminate the pattern of the reticle R by the first light. The exposure slit 321 is disposed between the exposure light source 310 and the reticle stage 330. More specifically, the exposure slit 321 is disposed between the illumination module 320 and the reticle stage 330. The first light passes through the exposure slit 321 to expose the pattern of the reticle R. The exposure slit 321 is generally at least as wide as an exposure field of the reticle R, but only a fraction of a length of the reticle R. The projection module 340 is configured to project the pattern of the reticle R onto the wafer W by the first light provided from the exposure light source 310 and penetrated through the pattern of the reticle R. The wafer stage 350 is configured to position the wafer W. The exposure light source 310 is disposed above the reticle stage 330. In one implementation, the alignment sensor 390 is disposed between the reticle stage 330 and the wafer stage 350, as shown in FIG. 3A. In some implementations, the alignment sensor 390 is disposed on the wafer stage 350, as shown in FIG. 3B. The alignment sensor 390 may be an image sensor.

The exposure apparatus 300 may further include a first driving unit 334, a second driving unit 354, a first interferometer 335, a second interferometer 355, a control unit 370, and a reticle determination unit 360. The first driving unit 334 is coupled to the reticle stage 330 and configured to drive the reticle stage 330. The second driving unit 354 is coupled to the wafer stage 350 and configured to drive the wafer stage 350. The first interferometer 335 is configured to measure a position of the reticle stage 330. The second interferometer 355 is configured to measure a position of the wafer stage 350. The control unit 370 is coupled to the first driving unit 334 and the second driving unit 354 and configured to control a driving pattern of the first driving unit 334 and the second driving unit 354. The control unit 370 is also coupled to the alignment sensor 390 to determine the alignment error of the reticle R based on the second light detected by the alignment sensor 390. The reticle determination unit 360 is disposed on the reticle stage 330 and configured to determine a feature of the reticle R.

The reticle stage 330 positions the reticle R by moving the reticle R in the Y-axis direction. The reticle stage 330 includes a reticle stage base 332 and a reticle holder 333; the reticle holder 333 is disposed on the reticle stage base 332 and for holding the reticle R over the reticle stage base 332. The first driving unit 334 drives the reticle stage base 332 according to the driving pattern. The first interferometer 335 continuously measures the position of the reticle stage base 332. The control unit 370 controls the position of the reticle stage 330 by using the first driving unit 334 at high precision.

The reticle determination unit 360 determines the feature of the reticle R placed on the reticle stage base 332. The reticle determination unit 360 is constructed by, for example, a reading unit that reads an identifier such as a barcode formed on the reticle R. Also, the reticle determination unit 360 may be constructed by an image sensing unit and an image processing unit; the image sensing unit senses the image of the reticle R, such as an area sensor, reflective sensor, or camera; and the image processing unit processes an image sensed by the image sensing unit. The feature of the reticle R includes, for example, at least one of the type of the reticle and the shape of the reticle. The type of the reticle may vary. Examples are a general reticle (e.g., a reticle on which a circuit pattern is drawn) used to fabricate a semiconductor device, and a special reticle used for a special purpose. The special reticle may include various jigs and is not limited to the reticle on which a circuit pattern is formed.

The projection module 340 projects the pattern of the reticle R illuminated by the light from the illumination module 320 at a predetermined magnification, such as ¼ or ⅕, onto the wafer W. The projection module 340 may employ a first optical module solely including a plurality of lens elements, a second optical module including a plurality of lens elements and at least one concave mirror (e.g., a catadioptric optical system), a third optical module including a plurality of lens elements and at least one diffractive optical element such as a kinoform, and a full mirror module. Any necessary correction of the chromatic aberration may be performed by using a plurality of lens elements made from soda-lime glass materials having different dispersion values (or Abbe values), or by arranging a diffractive optical element to disperse the light in a direction opposite to that of the lens elements.

The wafer stage 350 positions the wafer W by moving the wafer W in the X-axis and Y-axis directions. In this implementation, the wafer stage 350 includes a wafer stage base 352 on which the wafer W is placed, a wafer holder 353 for holding the wafer W on the wafer stage base 352, and a second driving unit 354 for driving the wafer stage base 352. A second interferometer 355 continuously measures the position of the wafer stage base 352. The control unit 370 controls the position of the wafer stage base 352 by using the second driving unit 354 at high precision.

The control unit 370 includes a central processing unit (CPU) and a memory, and controls the overall operation of the exposure apparatus 300. The control unit 370 controls an exposure process of transferring the pattern of the reticle R onto the wafer W.

Referring to FIG. 3C, a schematic diagram showing the exposure process of the exposure apparatus 300 of FIG. 3A is illustrated. During the exposure process, the exposure light source 310 generates the first light (as indicated by L1) to expose the pattern (including the circuit pattern P1 and the alignment mark P2) of the reticle R. The first light L1 penetrates through the pattern of the reticle R, passes through the projection module 340, and then exposes the wafer W. Therefore, the pattern (including the circuit pattern P1 and the alignment mark P2) of the reticle R is transferred onto the wafer W.

Referring to FIG. 3D, a schematic diagram showing an alignment error detecting process during the exposure process of the exposure apparatus 300 of FIG. 3A is illustrated.

During the exposure process, the reticle R may have alignment error due to thermal expansion caused by absorption of radiation energy of the first light L1 generated by the exposure light source 310. The alignment error of the reticle R can be detected without stopping the exposure process of the exposure apparatus 300. As shown in FIG. 3D, when the exposure light source 310 generates the first light L1 to expose the pattern of the reticle R, the alignment light source generates the second light (as indicated by L2) to expose the alignment mark P2 of the reticle R. The second light L2 penetrates through the alignment mark P2 of the reticle R. The alignment sensor 390 detects the second light L2 penetrated through the alignment mark P2 of the reticle R. The alignment error of the reticle R is then determined by the control unit 370 based on the second light L2 detected by the alignment sensor 390. The control unit 370 controls the first driving unit 334 to adjust the position of the reticle stage 330 to perform a realignment process between the reticle R and the wafer W. In some implementations, the control unit 370 controls the second driving unit 354 to adjust the position of the wafer stage 350 to perform the realignment process between the reticle R and the wafer W. In some implementations, the control unit 370 controls the first driving unit 334 and the second driving unit 354 to respectively adjust the positions of the reticle stage 330 and the wafer stage 350 to perform the realignment process between the reticle R and the wafer W. Such alignment error detection and realignment processes can be performed while the pattern of the reticle R is being exposed. Therefore, the exposure apparatus 300 of the second implementation of the present disclosure uses an additional light source for alignment error detection of the reticle R. The exposure apparatus 300 can perform alignment error detection of the reticle R without halting the exposure process. Therefore, the exposure apparatus 300 of the second implementation of the present disclosure can reduce the processing time of the exposure process, and hence improving the processing rate of the wafer W.

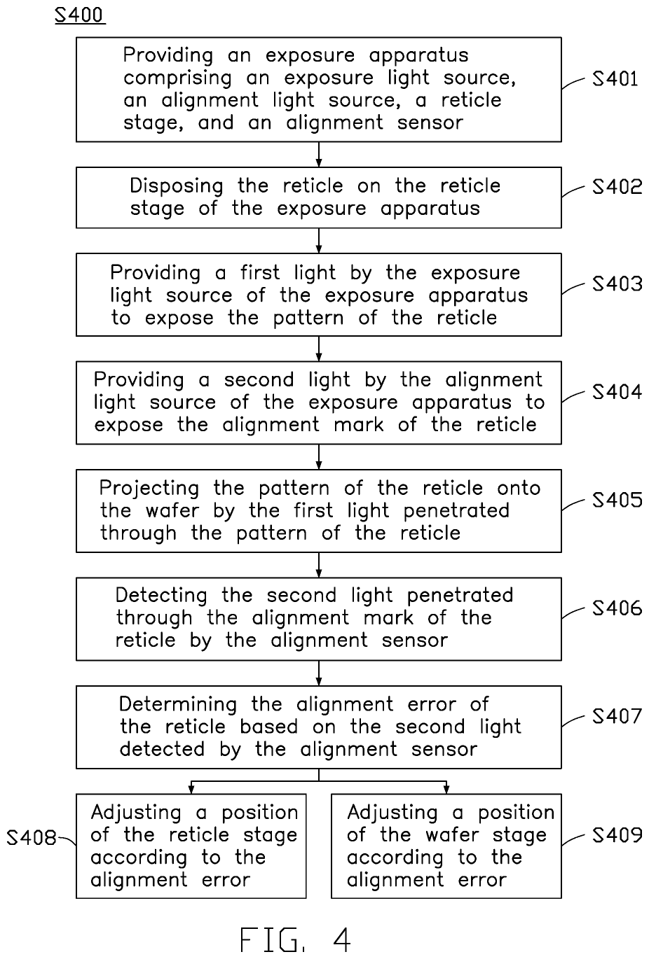

Referring to FIG. 4, a flowchart of a method S400 of detecting an alignment error of a reticle during an exposure process according to a third implementation of the present disclosure is provided. The reticle can be referred to the reticle R in FIG. 2B. The reticle R includes a transparent layer R1 and a metallic layer R2. The metallic layer R2 is disposed on the transparent layer R1 and forms the pattern P at one side of the reticle R. The pattern P includes at least one circuit pattern P1 and at least one alignment mark P2. The circuit pattern P1 is configured to form a circuit image on the wafer W. The alignment mark P2 is configured to align the reticle R to the wafer W. The method S400 includes actions S401 to S409.

In action S401, an exposure apparatus is provided. The exposure apparatus can be referred to the exposure apparatus 300 of the second implementation in FIGS. 3A to 3D. The exposure apparatus 300 includes an exposure light source 310, an alignment light source 380, a reticle stage 330, and an alignment sensor 390. The exposure light source 310 is configured to generate a first light to expose the pattern (including the circuit pattern P1 and the alignment mark P2) of the reticle R. The first light may be deep ultraviolet (DUV) light. The pattern (or the metallic layer R2) of the reticle R is exposed to the first light from the exposure light source 310 and then transferred to the wafer W. The alignment light source 380 is configured to generate a second light to expose the alignment mark P2 of the reticle R. The second light may be helium-neon laser light having a wavelength of about 632.8 nm. The alignment mark P2 of the reticle R is exposed to the second light from the alignment light source 380. The reticle stage 330 is configured to position the reticle R. The alignment sensor 390 is configured to detect the second light provided from the alignment light source 380 and penetrated through the alignment mark P2 of the reticle R for determining an alignment error of the reticle R. The exposure apparatus 300 further includes an illumination module 320, an exposure slit 321, a projection module 340, and a wafer stage 350. The illumination module 320 is configured to illuminate the pattern of the reticle R by the first light. The exposure slit 321 is disposed between the exposure light source 310 and the reticle stage 330. The first light passes through the exposure slit 321 to expose the pattern of the reticle R. The projection module 340 is configured to project the pattern of the reticle R onto the wafer W by the first light provided from the exposure light source 310 and penetrated through the pattern of the reticle R. The wafer stage 350 is configured to position the wafer W. The exposure apparatus 300 may further include a first driving unit 334, a second driving unit 354, a first interferometer 335, a second interferometer 355, a control unit 370, and a reticle determination unit 360. The first driving unit 334 is coupled to the reticle stage 330 and configured to drive the reticle stage 330. The second driving unit 354 is coupled to the wafer stage 350 and configured to drive the wafer stage 350. The first interferometer 335 is configured to measure a position of the reticle stage 330. The second interferometer 355 is configured to measure a position of the wafer stage 350. The control unit 370 is coupled to the first driving unit 334 and the second driving unit 354 and configured to control a driving pattern of the first driving unit 334 and the second driving unit 354. The control unit 370 is also coupled to the alignment sensor 390 to determine the alignment error of the reticle R based on the second light detected by the alignment sensor 390. The reticle determination unit 360 is disposed on the reticle stage 330 and configured to determine a feature of the reticle R.

In action S402, the reticle R is disposed on the reticle stage of the exposure apparatus 300. The reticle stage 330 positions the reticle R by moving the reticle R in the Y-axis direction. The reticle stage 330 includes a reticle stage base 332 and a reticle holder 333; the reticle holder 333 is disposed on the reticle stage base 332 and for holding the reticle R over the reticle stage base 332. The first driving unit 334 drives the reticle stage base 332 according to the driving pattern.

In action S403, the exposure light source 310 provides a first light to expose the patterns of the reticle R. In action S404, the alignment light source 380 provides a second light to expose the alignment mark of the reticle R. In action S405, the pattern of the reticle R is projected onto the wafer W by the first light penetrated through the pattern of the reticle R. In action S406, the second light penetrated through the alignment mark P2 of the reticle R is detected by the alignment sensor 390. The actions S403 to S406 can be referred to FIG. 3D. During the exposure process, the exposure light source 310 generates the first light (as indicated by L1) to expose the pattern (including the circuit pattern P1 and the alignment mark P2) of the reticle R. The first light L1 penetrates through the pattern of the reticle R, passes through the projection module 340, and then exposes the wafer W. In such way, the pattern (including the circuit pattern P1 and the alignment mark P2) of the reticle R is transferred onto the wafer W. During the exposure process, the reticle R may have alignment error due to thermal expansion caused by absorption of radiation energy of the first light L1 generated by the exposure light source 310. When the exposure light source 310 generates the first light L1 to expose the pattern of the reticle R, the alignment light source generates the second light (as indicated by L2) to expose the alignment mark P2 of the reticle R. The second light L2 penetrates through the alignment mark P2 of the reticle R. The alignment sensor 390 detects the second light L2 penetrated through the alignment mark P2 of the reticle R. During the exposure process, the reticle stage 330 and the wafer stage 350 are moved reciprocally to expose different areas of the reticle R to the wafer W by the first light L1, and each of the alignment mark P2 of the reticle can be exposed by the second light L2 when the reticle is moved reciprocally by the reticle stage 330. Therefore, the alignment error for each of the alignment mark can be detected.

In action S407, the alignment error of the reticle is determined based on the second light detected by the alignment sensor 390. The alignment error of the reticle R is determined by the control unit 370 based on the second light L2 detected by the alignment sensor 390. In actions S408 and S409, the realignment between the reticle and the wafer is performed according to the alignment error determined by the control unit 370. In one implementation, the position of the reticle stage 330 is adjusted in action S408 according to the alignment error. The control unit 370 controls the first driving unit 334 to adjust the position of the reticle stage 330 to perform realignment between the reticle R and the wafer W. In another implementation, the position of the wafer stage 350 is adjusted in action S409 according to the alignment error. The control unit 370 controls the second driving unit 354 to adjust the position of the wafer stage 350 to perform realignment between the reticle R and the wafer W. In some implementations, the positions of the reticle stage 330 and the wafer stage 350 are adjusted. The control unit 370 controls the first driving unit 334 and the second driving unit 354 to respectively adjust the positions of the reticle stage 330 and the wafer stage 350 to perform realignment between the reticle R and the wafer W.

As described above, the exposure apparatus of the implementations of the present disclosure uses an additional light source for alignment error detection of the reticle. While the exposure light source generates an exposure light to expose the pattern of the reticle, the alignment light source generates a detecting light to expose the alignment mark of the reticle. The detecting light penetrates through the alignment mark of the reticle and is detected by an alignment sensor for alignment error detection. The exposure apparatus of the implementations of the present disclosure can perform alignment error detection of the reticle without halting the exposure process. Therefore, the exposure apparatus of the implementations of the present disclosure can reduce the processing time of the exposure process, and hence improving the processing rate of the wafer.

The implementations shown and described above are only examples. Many details are often found in the art such as the other features of an exposure apparatus and a method of detecting an alignment error of a reticle. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. An exposure apparatus for transferring a pattern of a reticle onto a wafer, wherein the reticle has a metallic layer forming the pattern at one side of the reticle, the pattern includes at least one circuit pattern and at least one alignment mark, the exposure apparatus comprising:
an exposure light source configured to generate a first light to expose the pattern of the reticle;
an alignment light source configured to generate a second light to expose the alignment mark of the reticle;
a reticle stage configured to position the reticle; and
an alignment sensor configured to detect the second light penetrated through the alignment mark of the reticle for determining an alignment error of the reticle.

2. The exposure apparatus of claim 1, further comprising:
a projection module configured to project the pattern of the reticle onto the wafer by the first light penetrated through the pattern of the reticle; and
a wafer stage configured to position the wafer.

3. The exposure apparatus of claim 2, wherein the wafer stage comprises a wafer stage base and a wafer holder, and the wafer holder is disposed on the wafer stage base and for holding the wafer over the wafer stage base.

4. The exposure apparatus of claim 2, wherein the alignment light source is disposed above the reticle stage, and the alignment sensor is disposed between the reticle stage and the wafer stage.

5. The exposure apparatus of claim 2, wherein the alignment light source is disposed above the reticle stage, and the alignment sensor is disposed on the wafer stage.

6. The exposure apparatus of claim 2, further comprising:
a first driving unit coupled to the reticle stage and configured to drive the reticle stage; and
a second driving unit coupled to the wafer stage and configured to drive the wafer stage.

7. The exposure apparatus of claim 6, further comprising:
a first interferometer configured to measure a position of the reticle stage; and
a second interferometer configured to measure a position of the wafer stage.

8. The exposure apparatus of claim 6, further comprising a control unit coupled to the first driving unit and the second driving unit and configured to control a driving pattern of the first driving unit and the second driving unit.

9. The exposure apparatus of claim 1, further comprising a reticle determination unit disposed on the reticle stage and configured to determine a feature of the reticle.

10. The exposure apparatus of claim 1, further comprising an exposure slit disposed between the exposure light source and the reticle stage, wherein the first light passes through the exposure slit to expose the pattern of the reticle.

11. The exposure apparatus of claim 1, further comprising an illumination module configured to illuminate the pattern of the reticle by the first light.

12. The exposure apparatus of claim 1, wherein the metallic layer of the reticle is disposed on a transparent layer.

13. The exposure apparatus of claim 12, wherein the transparent layer of the reticle is a quartz layer or a soda-lime glass layer, and the metallic layer of the reticle is a chromium layer.

14. The exposure apparatus of claim 1, wherein the reticle stage comprises a reticle stage base and a reticle holder, and the reticle holder is disposed on the reticle stage base and for holding the reticle over the reticle stage base.

15. The exposure apparatus of claim 1, wherein the first light is deep ultraviolet (DUV) light, and the second light is helium-neon light.

16. A method of detecting an alignment error of a reticle during an exposure process, wherein the exposure process transfers a pattern of the reticle onto a wafer, the reticle has a metallic layer forming the pattern at one side of the reticle, the pattern includes at least one circuit pattern and at least one alignment mark, the method comprising:
providing an exposure apparatus comprising an exposure light source, an alignment light source, a reticle stage, and an alignment sensor;
disposing the reticle on the reticle stage of the exposure apparatus;
providing a first light by the exposure light source of the exposure apparatus to expose the pattern of the reticle;
providing a second light by the alignment light source of the exposure apparatus to expose the alignment mark of the reticle;
projecting the pattern of the reticle onto the wafer by the first light penetrated through the pattern of the reticle;
detecting the second light penetrated through the alignment mark of the reticle by the alignment sensor; and
determining the alignment error of the reticle based on the second light detected by the alignment sensor.

17. The method of claim 16, further comprising:
adjusting a position of the reticle stage according to the alignment error, after the alignment error of the reticle is determined.

18. The method of claim 16, wherein the exposure apparatus further comprises a wafer stage configure to position the wafer, and after the alignment error of the reticle is determined, the method further comprises adjusting a position of the wafer stage according to the alignment error.

19. The method of claim 16, wherein the first light is deep ultraviolet (DUV) light, and the second light is helium-neon light.

20. The method of claim 16, wherein the exposure apparatus further comprises a projection module configured to project the pattern of the reticle onto the wafer by the second light penetrated through the pattern of the reticle.
